(19) United States
(12) Patent Application Publication
(10) Pub. No.: US 2024/0209490 A1
(43) Pub. Date: Jun. 27, 2024

(54) MASK ASSEMBLY AND DEPOSITION APPARATUS INCLUDING THE SAME

(71) Applicant: Samsung Display Co., LTD., Yongin-si (KR)

(72) Inventors: SUNGYONG LEE, Yongin-si (KR); CHUNYOUNG PARK, Yongin-si (KR); YOUNG-MOOK CHOI, Yongin-si (KR); CHEOLRAE JO, Yongin-si (KR)

(21) Appl. No.: 18/499,553

(22) Filed: Nov. 1, 2023

(30) Foreign Application Priority Data
Dec. 27, 2022 (KR) 10-2022-0185496

(51) Int. Cl. C23C 14/04; C23C 14/24; H10K 71/16

(52) U.S. Cl. CPC C23C 14/042; C23C 14/24; H10K 71/166; H10K 71/164

(57) ABSTRACT

A mask assembly includes a stage having a rectangular shape in a plan view, and including a first surface and a second surface opposite to each other and extending in a first direction, where the stage includes a first magnet adjacent to the first surface, a first protrusion protruding from the first surface of the stage in a second direction crossing the first direction, and a second protrusion protruding from the second surface of the stage in a third direction opposite to the second direction, where the second protrusion includes a second magnet.

This application claims priority to Korean Patent Application No. 10-2022-0185496, filed on Dec. 27, 2022, and all the benefits accruing therefrom under 35 U.S.C. § 119, the content of which in its entirety is herein incorporated by reference.

### BACKGROUND

### 1. Field

Embodiments of the disclosure relate to a mask assembly. More specifically, embodiments of the disclosure relate to a mask assembly and a deposition apparatus including the mask assembly.

### 2. Description of the Related Art

A display device may include a pixel electrode, a common electrode, and a hole injection layer, a hole transport layer, a light emitting layer, an electron transport layer and an electron injection layer disposed between the pixel electrode and the common electrode. For example, the hole injection layer, the hole transport layer, the light emitting layer, the electron transport layer and the electron injection layer may be formed by depositing an organic material on a substrate through a deposition process. The deposition process may be performed by attaching a mask having a same pattern as a pattern of the light emitting layer or the like to the substrate on which deposition is to be performed.

### SUMMARY

Embodiments provide a mask assembly with improved productivity.

Embodiments provide a deposition apparatus including the mask assembly.

A mask assembly according to an embodiment of the disclosure includes a stage having a rectangular shape in a plan view and including a first surface and a second surface opposite to each other and extending in a first direction, where the stage includes a first magnet adjacent to the first surface, a first protrusion protruding from the first surface of the stage in a second direction crossing the first direction, and a second protrusion protruding from the second surface of the stage in a third direction opposite to the second direction, where the second protrusion includes a second magnet.

In an embodiment, the first magnet and the second magnet may have a same polarity as each other.

In an embodiment, a height from a bottom surface of the stage to the first magnet may be the same as a height from the bottom surface of the stage to the second magnet.

In an embodiment, a height from a bottom surface of the stage to the first protrusion may be greater than a height from the bottom surface of the stage to the second protrusion.

In an embodiment, the first magnet may be embedded in the first surface, and the second magnet may be embedded in the second protrusion.

In an embodiment, the mask assembly may further include a mask frame in which an opening is defined, and a mask fixed to the mask frame.

A mask assembly according to an embodiment of the disclosure includes a stage having a rectangular shape in a plan view, and including a first surface and a second surface opposite to each other and extending in a first direction, where the stage includes a first damper adjacent to the first surface, a first protrusion protruding from the first surface of the stage in a second direction crossing the first direction, and a second protrusion protruding from the second surface of the stage in a third direction opposite to the second direction, where the second protrusion includes a second damper.

In an embodiment, each of the first damper and the second damper may include a spring.

In an embodiment, each of the first damper and the second damper may include a cushion member.

In an embodiment, a height from a bottom surface of the stage to the first damper may be the same as a height from the bottom surface of the stage to the second damper.

In an embodiment, a height from a bottom surface of the stage to the first protrusion may be greater than a height from the bottom surface of the stage to the second protrusion.

In an embodiment, the mask assembly may further include a mask frame in which an opening is defined, and a mask fixed to the mask frame.

A deposition apparatus according to an embodiment of the disclosure includes a chamber, a transfer roller disposed inside the chamber, a first mask assembly disposed on the transfer roller and transferred along the transfer roller, and a second mask assembly disposed on the transfer roller, adjacent to the first mask assembly in a first direction, and transferred along the transfer roller. In such an embodiment, each of the first mask assembly and the second mask assembly includes a stage having a rectangular shape in a plan view, and including a first surface and a second surface opposite to each other and extending in a second direction crossing the first direction, where the stage includes a first magnet adjacent to the first surface, a first protrusion protruding from the first surface of the stage in a third direction opposite to the first direction, and a second protrusion protruding from the second surface of the stage in the first direction, where the second protrusion includes a second magnet.

In an embodiment, the first magnet and the second magnet may have a same polarity as each other.

In an embodiment, a height from a bottom surface of the stage to the first magnet may be the same as a height from the bottom surface of the stage to the second magnet.

In an embodiment, the first magnet of the second mask assembly may be adjacent to the second magnet of the first mask assembly in the first direction.

In an embodiment, a height from a bottom surface of the stage to the first protrusion may be greater than a height from the bottom surface of the stage to the second protrusion.

In an embodiment, the first protrusion of the second mask assembly may be adjacent to the second protrusion of the first mask assembly in a fourth direction crossing each of the first, second and third directions.

In an embodiment, the first magnet may be embedded in the first surface, and the second magnet may be embedded in the second protrusion.

In an embodiment, the deposition apparatus may further include a plurality of deposition sources disposed inside the chamber under the first mask assembly and the second mask assembly.

In a deposition apparatus according to embodiments of the disclosure, the deposition apparatus may include mask assemblies including a first magnet and a second magnet. In such embodiments, the first magnet and the second magnet may have a same polarity as each other. In such embodiments, each of the mask assemblies may be transferred along transfer rollers in a chamber. While each of the mask assemblies is being transferred in the chamber, a gap between the mask assemblies adjacent to each other may be maintained at a relatively small distance by a repulsive force between the first magnet and the second magnet.

Accordingly, collisions may not occur between the mask assemblies, and relatively more of mask assemblies may be effectively accommodated in the chamber, such that an efficiency of a deposition process may be improved.

### BRIEF DESCRIPTION OF THE DRAWINGS

FIG. 1 is a cross-sectional view illustrating a deposition apparatus according to an embodiment of the disclosure.

FIG. 2 is a perspective view illustrating an embodiment of a mask assembly included in the deposition apparatus of FIG. 1.

FIG. 3 is an enlarged cross-sectional view of area A of FIG. 1.

FIG. 4 is a perspective view illustrating an alternative embodiment of a mask assembly included in the deposition apparatus of FIG. 1.

FIG. 5 is a cross-sectional view illustrating a deposition apparatus according to an alternative embodiment of the disclosure.

FIG. 6 is a perspective view illustrating an embodiment of a mask assembly included in the deposition apparatus of FIG. 5.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings. The same reference numerals are used for the same components in the drawings, and any repetitive detailed descriptions of the same components will be omitted.

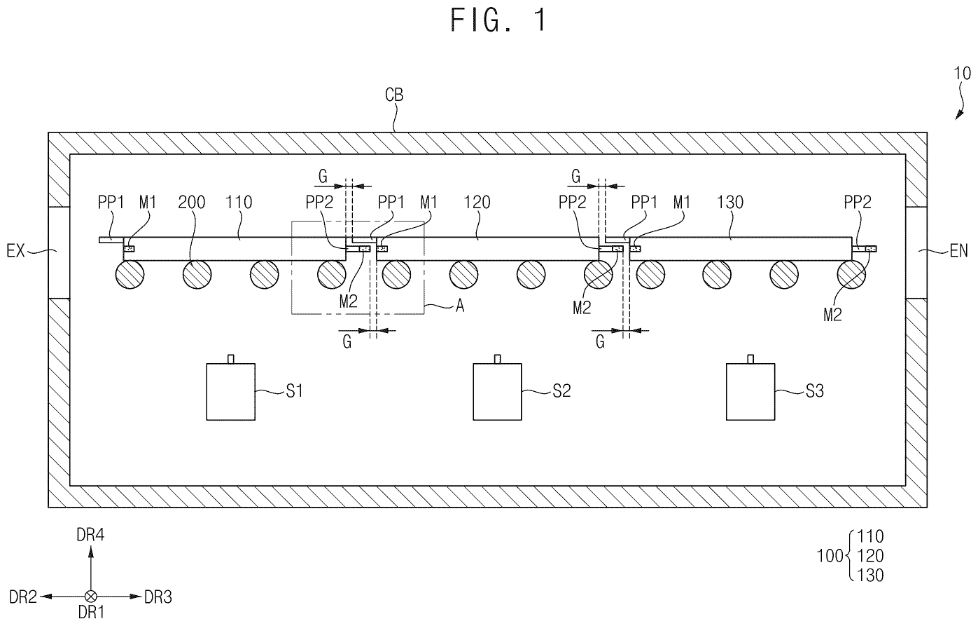

FIG. 1 is a cross-sectional view illustrating a deposition apparatus according to an embodiment of the disclosure.

Referring to FIG. 1, an embodiment of a deposition apparatus 10 may include a chamber CB, a plurality of mask assemblies 100, a first deposition source S1, a second deposition source S2, a third deposition source S3 and a plurality of transfer rollers 200.

The chamber CB may include an empty space therein. In an embodiment, the chamber CB may define a space in which a deposition process is performed in which a deposition material provided from each of the first, second and third deposition sources S1, S2 and S3 is deposited on a substrate. In an embodiment, an evaporation method may be performed in which the deposition material is evaporated and deposited on the substrate in the deposition process. In this process, inside of the chamber CB may be maintained in a vacuum.

The chamber CB may include an inlet EN through which the mask assemblies 100 are put in and an outlet EX through which the mask assemblies 100 are taken out. The inlet EN may be formed or defined on one side of the chamber CB, and the outlet EX may be formed or defined on the other side of the chamber CB. Therefore, the mask assemblies 100 may be put into the chamber CB through the inlet EN, and the mask assemblies 100 may be taken out of the chamber CB through the outlet EX.

Each of the mask assemblies 100 may be parallel to a plane defined by a first direction DR1 and a second direction DR2 crossing the first direction DR1. For example, the first direction DR1 and the second direction DR2 may be perpendicular to each other. Each of the mask assemblies 100 may be coupled to the substrate.

Each of the mask assemblies 100 may include a first mask assembly 110, a second mask assembly 120 and a third mask assembly 130. The first, second and third mask assemblies 110, 120 and 130 may be arranged along a third direction DR3 opposite to the second direction DR2. In addition, the first, second and third mask assemblies 110, 120 and 130 may be adjacent to each other. In an embodiment, for example, the second mask assembly 120 may be adjacent to the first mask assembly 110 in the third direction DR3, and the third mask assembly 130 may be adjacent to the second mask assembly 120 in the third direction DR3.

In an embodiment, each of the mask assemblies 100 may include a first protrusion PP1 and a second protrusion PP2. In an embodiment, for example, the first protrusion PP1 may protrude from a first surface of each of the mask assemblies 100 in the second direction DR2. In addition, the second protrusion PP2 may protrude from a second surface opposite to the first surface of each of the mask assemblies 100 in the third direction DR3. Here, the first surface of each of the mask assemblies 100 may be a surface facing in the second direction DR2, and the second surface of each of the mask assemblies 100 may be a surface facing in the third direction DR3.

The second protrusion PP2 of the first mask assembly 110 and the first protrusion PP1 of the second mask assembly 120 may overlap each other in a plan view. In an embodiment, the second protrusion PP2 of the first mask assembly 110 and the first protrusion PP1 of the second mask assembly 120 may overlap each other in a fourth direction DR4. The fourth direction DR4 may be a direction crossing each of the first, second and third directions DR1, DR2 and DR3. In an embodiment, for example, the fourth direction DR4 may be perpendicular to each of the first, second and third directions DR1, DR2 and DR3. In addition, the second protrusion PP2 of the second mask assembly 120 and the first protrusion PP1 of the third mask assembly 130 may overlap each other in a plan view. In an embodiment, the second protrusion PP2 of the second mask assembly 120 and the first protrusion PP1 of the third mask assembly 130 may overlap each other in the fourth direction DR4. Accordingly, the evaporated deposition material may be effectively prevented from contaminating the chamber CB.

In an embodiment, each of the mask assemblies 100 may include a first magnet M1 and a second magnet M2. The first magnet M1 may be adjacent to the first surface of each of the mask assemblies 100, and the second magnet M2 may be adjacent to the second surface of each of the mask assemblies 100.

In such an embodiment, the first magnet M1 included in the second mask assembly 120 may be adjacent to the second magnet M2 included in the first mask assembly 110 in the third direction DR3. In addition, the first magnet M1 included in the third mask assembly 130 may be adjacent to the second magnet M2 included in the second mask assembly 120 in the third direction DR3.

In an embodiment, the first magnet M1 and the second magnet M2 may have a same polarity as each other. In an embodiment, for example, each of the first magnet M1 and the second magnet M2 may have a north (N) pole. In an alternative embodiment, for example, each of the first magnet M1 and the second magnet M2 may have a south (S) pole.

Accordingly, a repulsive force due to magnetic force may be generated between the first magnet M1 and the second magnet M2 adjacent to each other. In such an embodiment, the repulsive force due to magnetic force may be generated between the second magnet M2 included in the first mask assembly 110 and the first magnet M1 included in the second mask assembly 120. In addition, the repulsive force due to magnetic force may be generated between the second magnet M2 included in the second mask assembly 120 and the first magnet M1 included in the third mask assembly 130.

In an embodiment, a gap G between the mask assemblies 100 adjacent to each other may be maintained at a predetermined distance or greater. In such an embodiment, the mask assemblies 100 adjacent to each other may not collide with each other due to the repulsive force generated between the first magnet M1 and the second magnet M2 adjacent to each other. That is, the gap G between the first mask assembly 110 and the second mask assembly 120 and the gap G between the second mask assembly 120 and the third mask assembly 130 may be maintained at the predetermined distance or greater.

In such a embodiment, each of the gap G between the second surface of the first mask assembly 110 and one end of the first protrusion PP1 of the second mask assembly 120 and the gap G between the second surface of the second mask assembly 120 and one end of the first protrusion PP1 of the third mask assembly 130 may be maintained at the predetermined distance or greater.

In such an embodiment, each of the gap G between one end of the second protrusion PP2 of the first mask assembly 110 and the first surface of the second mask assembly 120 and the gap G between one end of the second protrusion PP2 of the second mask assembly 120 and the first surface of the third mask assembly 130 may be maintained at the predetermined distance or greater. In an embodiment, for example, the gap G may be maintained in a range of several millimeters (mm) to several tens of mm, but the disclosure is not limited thereto.

Each of the first, second and third deposition sources S1, S2 and S3 may evaporate the deposition material, and may provide the deposition material to each of the mask assemblies 100. In an embodiment, the first, second and third deposition sources S1, S2 and S3 may be spaced apart from each other in the chamber CB, and may be arranged in the third direction DR3. The deposition material evaporated from each of the first, second and third deposition sources S1, S2 and S3 may be provided in the fourth direction DR4.

In an embodiment, each of the first, second and third deposition sources S1, S2 and S3 may provide an organic material. In an embodiment, for example, the first deposition source S1 may provide an organic material that forms an electron injection layer, the second deposition source S2 may provide an organic material that forms a light emitting layer, and the third deposition source S3 may provide an organic material that forms a hole injection layer. In a alternative embodiment, the first, second and third deposition sources S1, S2 and S3 may provide a metal material. However, the disclosure is not limited thereto.

The transfer rollers 200 may be arranged in the second direction DR2 and the third direction DR3 inside the chamber CB. The mask assemblies 100 may be disposed on the transfer rollers 200. In an embodiment, the mask assemblies 100 may contact the transfer rollers 200.

The transfer rollers 200 may guide a movement of each of the mask assemblies 100. That is, the transfer rollers 200 may transfer each of the mask assemblies 100. In an embodiment, each of the mask assemblies 100 put into the chamber CB through the inlet EN may be transferred along the transfer rollers 200, and may be taken out of the chamber CB through the outlet EX. Accordingly, the deposition material provided from the third deposition source S3, the deposition material provided from the second deposition source S2 and the deposition material provided from the first deposition source S1 may be sequentially deposited on the substrate coupled to each of the mask assemblies 100.

Although FIG. 1 illustrates an embodiment where the deposition apparatus 10 includes three mask assemblies 110, 120 and 130, the disclosure is not limited thereto. Alternatively, the deposition apparatus 10 may include two or less or four or more mask assemblies.

In addition, although FIG. 1 illustrates an embodiment where the deposition apparatus 10 includes three deposition sources S1, S2 and S3, the disclosure is not limited thereto. Alternatively, the deposition apparatus 10 may include two or less or four or more deposition sources.

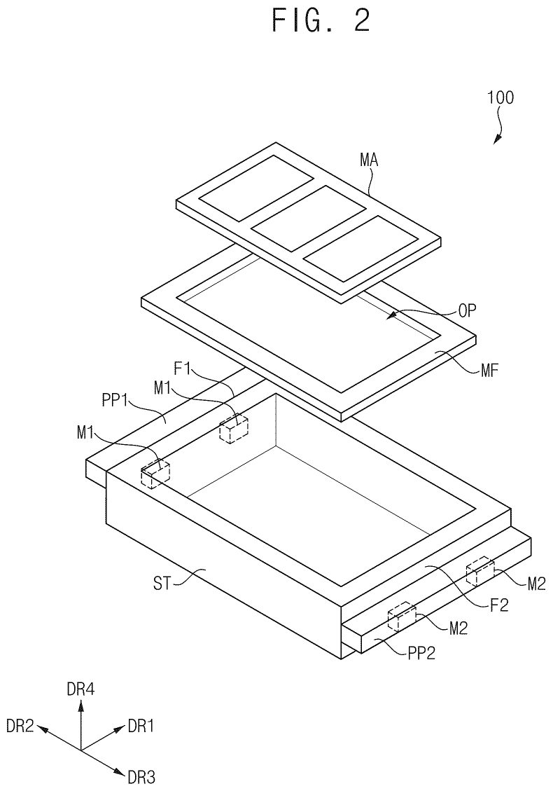

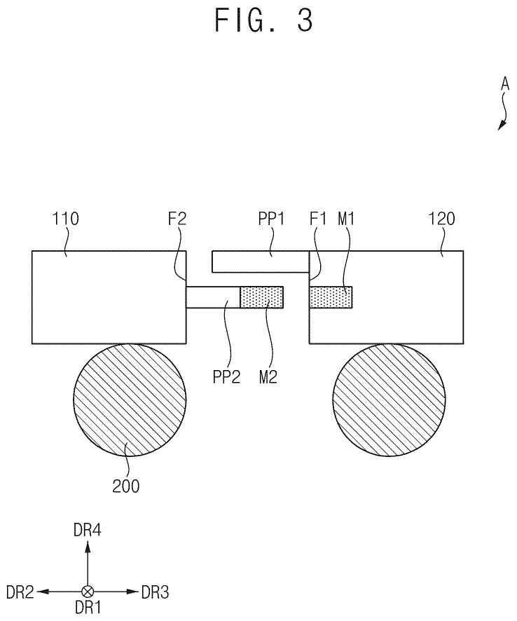

FIG. 2 is a perspective view illustrating a mask assembly included in the deposition apparatus of FIG. 1. FIG. 3 is an enlarged cross-sectional view of area A of FIG. 1.

Referring to FIGS. 1, 2 and 3, in an embodiment, each of the mask assemblies 100 may include a stage ST, a mask frame MF and a mask MA.

In an embodiment, the stage ST may have a rectangular shape in a plan view. The stage ST may include a first surface F1 and a second surface F2 extending in the first direction DR1. The first surface F1 and the second surface F2 may be opposite to each other.

The stage ST may include the first protrusion PP1 and the second protrusion PP2. The first protrusion PP1 may protrude from the first surface F1 in the second direction DR2, and the second protrusion PP2 may protrude from the second surface F2 in the third direction DR3.

In an embodiment, a height from a bottom surface of the stage ST to the first protrusion PP1 may be greater than a height from the bottom surface of the stage ST to the second protrusion PP2. The first protrusion PP1 and the second protrusion PP2 may overlap each other in a plan view, but may not collide with each other because the heights of the first protrusion PP1 and the second protrusion PP2 in the fourth direction DR4 are different from each other. That is, the first protrusion PP1 may be adjacent to the second protrusion PP2 in the fourth direction DR4. In an embodiment, the first protrusion PP1 included in the second mask assembly 120 may be adjacent to the second protrusion PP2 included in the first mask assembly 110 in the fourth direction DR4. In addition, the first protrusion PP1 included in the third mask assembly 130 may be adjacent to the second protrusion PP2 included in the second mask assembly 120 in the fourth direction DR4.

In an embodiment, the stage ST may include a first magnet M1 and a second magnet M2. The first magnet M1 may be adjacent to the first surface F1 of the stage ST, and the second magnet M2 may be adjacent to the second surface F2 of the stage ST. In an embodiment, the first magnet M1 may be embedded in the first surface F1, and the second magnet M2 may be embedded in the second protrusion PP2, but the disclosure is limited thereto.

In an embodiment, a height from the bottom surface of the stage ST to the first magnet M1 may be a same as a height from the bottom surface of the stage ST to the second magnet M2. That is, in the stage ST, the first magnet M1 may be spaced apart from the second magnet M2 in the second direction DR2. Accordingly, the repulsive force may be generated between the first magnet M1 and the second magnet M2 in the second direction DR2.

The mask frame MF may be coupled to the stage ST. An opening OP may be defined in the mask frame MF.

The mask MA may be coupled to the mask frame MF. in an embodiment, the mask MA may be coupled to the mask frame MF to overlap the opening OP of the mask frame MF. In an embodiment, the mask MA may be fixed to the mask frame MF, and may be supported by the mask frame MF. In such an embodiment, since edges of the mask MA are supported by the mask frame MF, rigidity of the mask MA may be further improved and handling of the mask MA may be facilitated.

At least one deposition opening may be defined in the mask MA. The deposition opening may be a portion through which the deposition material passes in the deposition process. In such an embodiment, the deposition opening may correspond to each of cell regions of the substrate. In an embodiment, for example, the mask MA may be an open mask. In an alternative embodiment, for example, the mask MA may be a fine metal mask.

Although FIG. 2 illustrates an embodiment where each of the mask assemblies 100 includes two first magnets M1 and two second magnets M2, but the disclosure is not limited thereto. Alternatively, each of the mask assemblies 100 may include one or three or more first magnets M1 and one or three or more second magnets M2. In addition, each of the first magnet M1 and the second magnet M2 may have various sizes and various magnetic force strengths.

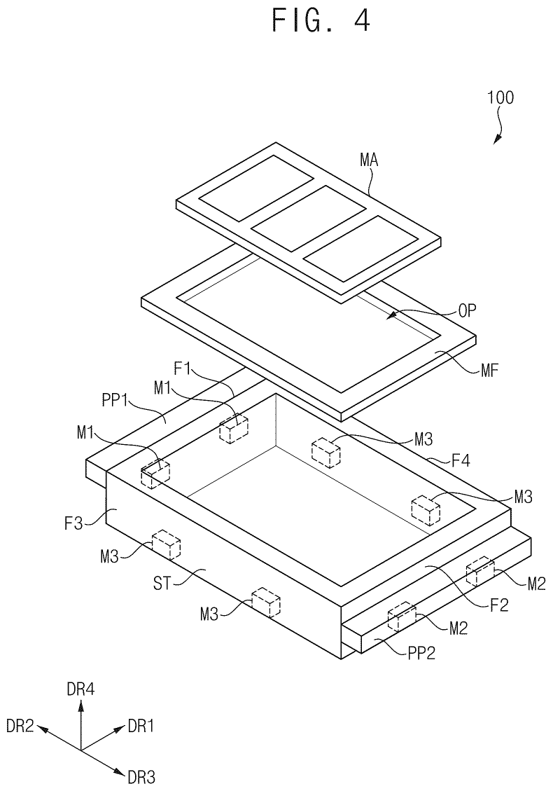

FIG. 4 is a perspective view illustrating an alternative embodiment of a mask assembly included in the deposition apparatus of FIG. 1.

Referring to FIGS. 1 and 4, in an embodiment, each of the mask assemblies 100 may include a stage ST, a mask frame MF, and a mask MA.

Hereinafter, any repetitive detailed descriptions of the same or like elements in FIG. 4 as those of the mask assembly 100 described above with reference to FIG. 2 will be omitted or simplified.

In an embodiment, the stage ST may include a third surface F3 and a fourth surface F4 extending in the second direction DR2. The third surface F3 and the fourth surface F4 may be opposite to each other.

In an embodiment, the stage ST may further include a plurality of third magnets M3. The third magnets M3 may be adjacent to the third surface F3 and the fourth surface F4. In an embodiment, the third magnets M3 may be embedded in the third surface F3 and the fourth surface F4, but the disclosure is not limited thereto.

Each of the third magnets M3 may guide each of the mask assemblies 300 to be transferred along the transfer rollers 200. In an embodiment, each of the transfer rollers 200 may include a magnet having a same polarity as the third magnets M3. Accordingly, a repulsive force due to magnetic force may be generated between the third magnets M3 and the transfer rollers 200, such that a running straightness of each of the mask assemblies 100 may be improved.

The deposition apparatus 10 according to an embodiment of the disclosure may include the mask assemblies 100 including the first magnet M1 and the second magnet M2. The first magnet M1 and the second magnet M2 may have the same polarity as each other. Each of the mask assemblies 100 may be transferred along the transfer rollers 200. While each of the mask assemblies 100 is being transferred, the gap G between the mask assemblies 100 adjacent to each other may be maintained at a relatively small distance by the repulsive force between the first magnet M1 and the second magnet M2. Accordingly, collisions may not occur between the mask assemblies 100, and relatively more of the mask assemblies 100 may be effectively accommodated in the chamber CB, such that an efficiency of the deposition process may be improved.

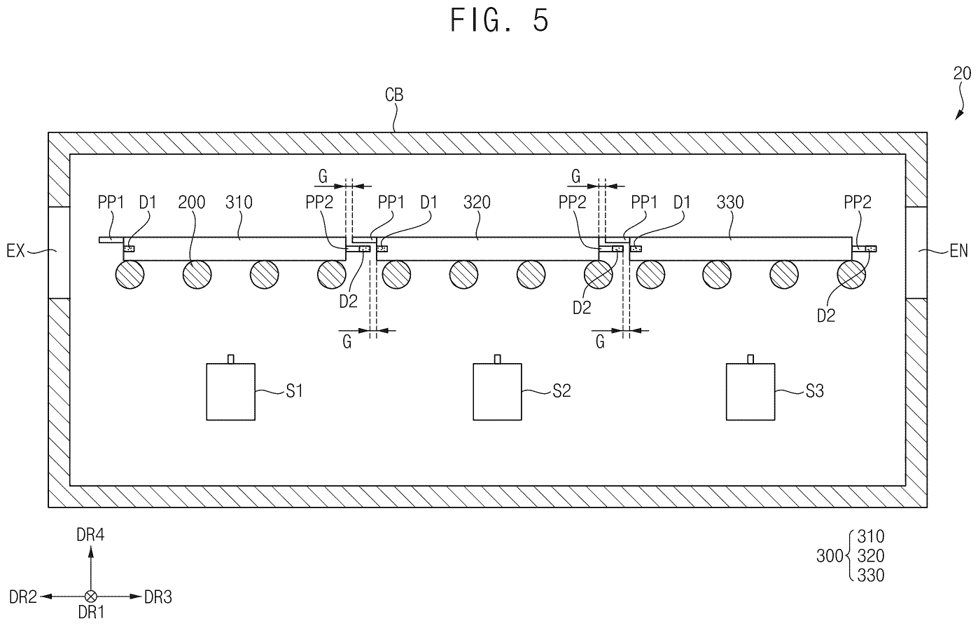

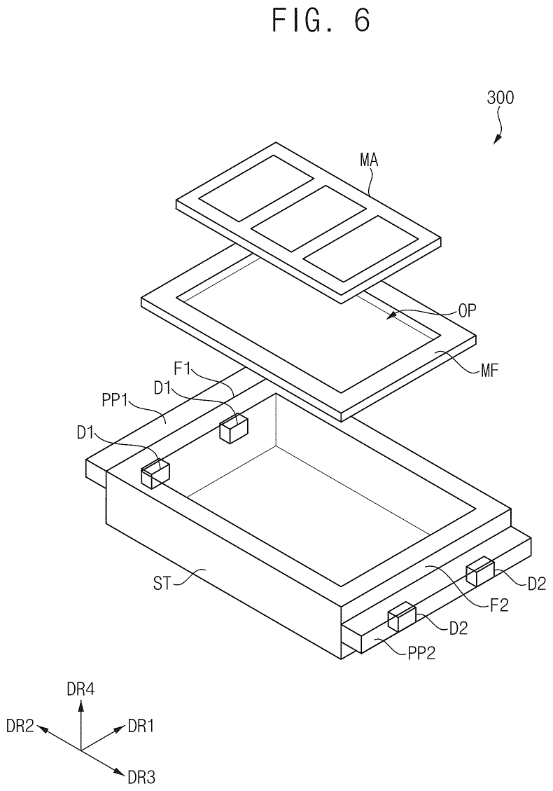

FIG. 5 is a cross-sectional view illustrating a deposition apparatus according to an alternative embodiment of the disclosure. FIG. 6 is a perspective view illustrating an embodiment of a mask assembly included in the deposition apparatus of FIG. 5.

Referring to FIGS. 5 and 6, an embodiment of a deposition apparatus 20 may include a chamber CB, a plurality of mask assemblies 300, a first deposition source S1, a second deposition source S2, a third deposition source S3 and a plurality of transfer rollers 200. Each of the mask assemblies 300 may include a stage ST, a mask frame MF and a mask MA.

Hereinafter, any repetitive detailed descriptions of the same or like elements in FIGS. 5 and 6 as those of the deposition apparatus 10 and the mask assemblies 100 described above with reference to FIG. 2 will be omitted or simplified.

In an embodiment, the mask assemblies 300 may include a first mask assembly 310, a second mask assembly 320 and a third mask assembly 330. The first, second and third mask assemblies 310, 320 and 330 may be arranged along the third direction DR3. In addition, the first, second and third mask assemblies 310, 320 and 330 may be adjacent to each other. In an embodiment, for example, the second mask assembly 320 may be adjacent to the first mask assembly 310 in the third direction DR3, and the third mask assembly 330 may be adjacent to the second mask assembly 320 in the third direction DR3.

In an embodiment, each of the mask assemblies 300 may include the first protrusion PP1 and the second protrusion PP2. In an embodiment, the stage ST included in each of the mask assemblies 300 may include the first protrusion PP1 and the second protrusion PP2. A height from a bottom surface of the stage ST to the first protrusion PP1 may be greater than a height from the bottom surface of the stage ST to the second protrusion PP2.

The second protrusion PP2 of the first mask assembly 310 and the first protrusion PP1 of the second mask assembly 320 may overlap each other in a plan view. In an embodiment, the first protrusion PP1 included in the second mask assembly 320 may be adjacent to the second protrusion PP2 included in the first mask assembly 310 in the fourth direction DR4.

In such an embodiment, the second protrusion PP2 of the second mask assembly 320 and the first protrusion PP1 of the third mask assembly 330 may overlap each other in a plan view. The first protrusion PP1 included in the third mask assembly 330 may be adjacent to the second protrusion PP2 included in the second mask assembly 320 in the fourth direction DR4.

In such an embodiment, the first protrusion PP1 and the second protrusion PP2 may overlap each other in a plan view, but may not collide with each other because the heights of the first protrusion PP1 and the second protrusion PP2 in the fourth direction DR4 are different from each other.

In an embodiment, each of the mask assemblies 300 may include a first damper D1 and a second damper D2. In an embodiment, the stage ST included in each of the mask assemblies 300 may include at least one first damper D1 and at least one second damper D2.

In an embodiment, each of the first damper D1 and the second damper D2 may include a spring. In an alternative embodiment, each of the first damper D1 and the second damper D2 may include a cushion member. However, the disclosure is not limited thereto.

The first damper D1 may be adjacent to the first surface F1 of the stage ST, and the second damper D2 may be adjacent to the second surface F2 of the stage ST. In such an embodiment, the first damper D1 included in the second mask assembly 320 may be adjacent to the second damper D2 included in the first mask assembly 310 in the third direction DR3. In addition, the first damper D1 included in the third mask assembly 330 may be adjacent to the second damper D2 included in the second mask assembly 320 in the third direction DR3.

In an embodiment, a gap G between the mask assemblies 300 adjacent to each other may be maintained at a predetermined distance or greater. In such an embodiment, since each of the first damper D1 and the second damper D2 acts as a damping function to absorb external impact, the gap G may be maintained at the predetermined interval or greater.

In an embodiment, a height from the bottom surface of the stage ST to the first damper D1 may be the same as a height from the bottom surface of the stage ST to the second damper D2. That is, in the stage ST, the first damper D1 may be spaced apart from the second damper D2 in the second direction DR2.

The deposition apparatus 20 according to an embodiment of the disclosure may include the mask assemblies 300 including the first damper D1 and the second damper D2. Each of the mask assemblies 300 may be transferred along the transfer rollers 200. While each of the mask assemblies 100 is being transferred, the first damper D1 and the second damper D2 may absorb external impact. In such an embodiment, even if the gap G between the mask assemblies 300 adjacent to each other decreases, impact due to collision between the mask assemblies 300 may not be generated by the first damper D1 and the second damper D2. Accordingly, relatively more of the mask assemblies 300 may be effectively accommodated in the chamber CB such that an efficiency of the deposition process may be improved.

Embodiments of the disclosure can be applied to a manufacturing process of various display devices. In an embodiment, for example, the disclosure is applicable to a manufacturing process of various display devices such as display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask assembly comprising:
a stage having a rectangular shape in a plan view, and including a first surface and a second surface opposite to each other and extending in a first direction, wherein the stage includes a first magnet adjacent to the first surface;
a first protrusion protruding from the first surface of the stage in a second direction crossing the first direction; and
a second protrusion protruding from the second surface of the stage in a third direction opposite to the second direction, wherein the second protrusion includes a second magnet.

2. The mask assembly of claim 1, wherein the first magnet and the second magnet have a same polarity as each other.

3. The mask assembly of claim 1, wherein a height from a bottom surface of the stage to the first magnet is the same as a height from the bottom surface of the stage to the second magnet.

4. The mask assembly of claim 1, wherein a height from a bottom surface of the stage to the first protrusion is greater than a height from the bottom surface of the stage to the second protrusion.

5. The mask assembly of claim 1, wherein
the first magnet is embedded in the first surface, and
the second magnet is embedded in the second protrusion.

6. The mask assembly of claim 1, further comprising:
a mask frame in which an opening is defined; and
a mask fixed to the mask frame.

7. A mask assembly comprising:
a stage having a rectangular shape in a plan view, and including a first surface and a second surface opposite to each other and extending in a first direction, wherein the stage includes a first damper adjacent to the first surface;
a first protrusion protruding from the first surface of the stage in a second direction crossing the first direction; and
a second protrusion protruding from the second surface of the stage in a third direction opposite to the second direction, wherein the second protrusion includes a second damper.

8. The mask assembly of claim 7, wherein each of the first damper and the second damper includes a spring.

9. The mask assembly of claim 7, wherein each of the first damper and the second damper includes a cushion member.

10. The mask assembly of claim 7, wherein a height from a bottom surface of the stage to the first damper is the same as a height from the bottom surface of the stage to the second damper.

11. The mask assembly of claim 7, wherein a height from a bottom surface of the stage to the first protrusion is greater than a height from the bottom surface of the stage to the second protrusion.

12. The mask assembly of claim 7, further comprising:
a mask frame in which an opening is defined; and
a mask fixed to the mask frame.

13. A deposition apparatus comprising:
a chamber;
a transfer roller disposed inside the chamber;
a first mask assembly disposed on the transfer roller and transferred along the transfer roller; and
a second mask assembly disposed on the transfer roller, adjacent to the first mask assembly in a first direction, and transferred along the transfer roller,
wherein each of the first mask assembly and the second mask assembly includes:
a stage having a rectangular shape in a plan view, and including a first surface and a second surface opposite to each other and extending in a second direction crossing the first direction, wherein the stage includes a first magnet adjacent to the first surface;
a first protrusion protruding from the first surface of the stage in a third direction opposite to the first direction; and
a second protrusion protruding from the second surface of the stage in the first direction, wherein the second protrusion includes a second magnet.

14. The deposition apparatus of claim 13, wherein the first magnet and the second magnet have a same polarity as each other.

15. The deposition apparatus of claim 13, wherein a height from a bottom surface of the stage to the first magnet is the same as a height from the bottom surface of the stage to the second magnet.

16. The deposition apparatus of claim 15, wherein the first magnet of the second mask assembly is adjacent to the second magnet of the first mask assembly in the first direction.

17. The deposition apparatus of claim 13, wherein a height from a bottom surface of the stage to the first protrusion is greater than a height from the bottom surface of the stage to the second protrusion.

18. The deposition apparatus of claim 17, wherein the first protrusion of the second mask assembly is adjacent to the second protrusion of the first mask assembly in a fourth direction crossing each of the first, second and third directions.

19. The deposition apparatus of claim 13, wherein
the first magnet is embedded in the first surface, and
the second magnet is embedded in the second protrusion.

20. The deposition apparatus of claim 13. further comprising:
a plurality of deposition sources disposed inside the chamber under the first mask assembly and the second mask assembly.
